(19) United States
(12) Patent Application Publication
(10) Pub. No.: US 2010/0248460 A1
(43) Pub. Date: Sep. 30, 2010

(54) Method of forming information storage pattern

(76) Inventors: Jin-Il Lee, Seongnam-si (KR); Urazaev Vladimir, Suwon-si (KR); Jin-Ha Jeong, Yongin-si (KR); Seung-Back Shin, Seoul (KR); Sung-Lae Cho, Gwacheon-si (KR); Hyeong-Geun An, Hwaseong-si (KR); Dong-Hyun Im, Hwaseong-si (KR); Jung-Hyeon Kim, Hwaseong-si (KR)

Correspondence Address: LEE & MORSE, P.C., 3141 FAIRVIEW PARK DRIVE, SUITE 500, FALLS CHURCH, VA, 22042, US

(21) Appl. No.: 12/659,959

(22) Filed: Mar. 26, 2010

(30) Foreign Application Priority Data
Mar. 27, 2009 (KR) 10-2009-0026420

(51) Int. Cl. H01L 21/365; H01L 21/469; H01L 21/443; H01L 21/465

(52) U.S. Cl. 438/494; 438/763; 257/E21.46; 257/E21.463; 257/E21.487; 257/E21.485; 257/E21.478

(57) ABSTRACT

A method of forming an information storage pattern, includes placing a semiconductor substrate in a process chamber, injecting first, second and third process gases into the process chamber during a first process to form a lower layer on the substrate based on a first injection time and/or a first pause time, injecting the second process gas into the process chamber during a second process, wherein the second process gas is injected into the process chamber during a first elimination time, injecting a fourth process gas together with the second and third process gases into the process chamber during a third process in accordance with a second injection time and/or a second pause time to form an upper layer on the lower layer, and injecting the second process gas into the process chamber during a fourth process, wherein the second process gas is injected into the process chamber during a second elimination.

### BACKGROUND

1. Field

Exemplary embodiments are directed to methods of forming information storage patterns.

2. Description of the Related Art

In general, a phase change memory device may be fabricated to have a memory cell by forming a resistor to correspond to an information storage pattern disposed on a semiconductor substrate. The resistor may have a phase change material. The information storage pattern may have a lower electrode at a lower portion of the memory cell, and an upper electrode at an upper portion of the memory cell. The lower electrode may be formed to partially fill an opening of a selected interlayer insulating layer. The memory cell may be formed by etching the resistor that fills the opening and is disposed on the interlayer insulating layer. As a result, the memory cell may be disposed in the opening to expose the interlayer insulating layer.

However, the memory cell may not sufficiently fill the opening of the interlayer insulating layer on the lower electrode. This is because the resistor is formed using a chemical vapor deposition technique of a semiconductor deposition process. In the chemical vapor deposition technique, vapor reactions of source and reaction gases are induced on a semiconductor substrate to form reactive materials. In such a case, in the chemical vapor deposition technique, a purge gas may not be injected into a process chamber while a source gas and/or a reaction gas are injected.

Therefore, the reactive materials may be deposited on the semiconductor substrate without adjusting a deposition rate of the reactive materials. While the chemical vapor deposition technique is performed, the reactive materials may enable an entrance of the opening to be clogged without being conformally covered along the opening. As a result, the memory cell may not have a uniform ratio of atoms (Ge, Sb, Te) from a top surface of the lower electrode to the entrance of the opening. Further, the memory cell may not have a desired resistance uniformly from the top surface of the lower electrode to the entrance of the opening.

The upper electrode may be continuously formed on the interlayer insulating layer to cover the memory cell. The information storage pattern may not provide a phase change memory device with wanted electric bits through the lower electrode, the memory cell and the upper electrode.

### SUMMARY

Exemplary embodiments are therefore directed to methods of forming information storage patterns, which substantially overcome one or more of the problems due to the limitations and disadvantages of the related art.

Exemplary embodiments provide a method of forming an information storage pattern suitable for employing a chemical vapor deposition technique enabling process gases injected into a process chamber of semiconductor deposition equipment to correspond to different pulse shapes.

Exemplary embodiments provide a method of forming an information storage pattern capable of uniformly maintaining a ratio of atoms in a memory cell in contact with a lower electrode on a semiconductor substrate.

Exemplary embodiments are directed to a method of forming an information storage pattern, including placing a semiconductor substrate in a process chamber of semiconductor deposition equipment, injecting first, second and third process gases into the process chamber during a first process to form a lower layer on the semiconductor substrate in accordance with a first injection time and/or a first pause time, injecting the second process gas into the process chamber during a second process wherein the second process gas is injected into the process chamber during a first elimination time after completing the first process, injecting a fourth process gas together with the second and third process gases into the process chamber during a third process in accordance with a second injection time and/or a second pause time to form an upper layer on the lower layer, and injecting the second process gas into the process chamber during a fourth process, wherein the second process gas is injected into the process chamber during a second elimination time after completing the third process.

The first process gas may be periodically and repeatedly injected in accordance with the first injection time and the first pause time, and the second process gas is injected into the process chamber during periods corresponding to the first pause time, and the third process gas is injected into the process chamber during periods corresponding to the first injection time and the first pause time.

The semiconductor substrate may include an interlayer insulating layer and a lower electrode, the interlayer insulating layer includes an opening.

The method may include periodically and repeatedly performing the first, second, third, and fourth processes at least once, and to form a stacked layer on the semiconductor substrate, wherein the stacked layer includes a stacked structure having the lower layer and the upper layer in a periodic and repeated manner, and the stacked layer may be formed to fill the opening and cover the interlayer insulating layer, etching the stacked layer to expose the interlayer insulating layer, and to form a memory cell in the opening, and forming an upper electrode on the interlayer insulating layer to cover the memory cell.

The lower electrode may at least partially fill the opening, and injecting the first, second and third process gases may include forming the lower layer on the interlayer insulating layer to cover the lower electrode, and the lower layer includes a phase change material conformally covering the opening.

The upper layer may include a phase change material conformally covering the opening.

The fourth process gas may be periodically and repeatedly injected in accordance with the second injection time and the second pause time, the second process gas may be injected into the process chamber in accordance with the second pause time, and the third process gas may be injected into the process chamber during time periods corresponding to the second injection and pause times.

The first process gas and the fourth process gas may include a mixture of a germanium precursor and a tellurium precursor, and a mixture of an antimony precursor and a tellurium precursor, respectively.

The germanium precursor may include Ge(i-Pr)₃H, GeCl₄, Ge(Me)₄, Ge(Me)₄N₃, Ge(Et)₄, Ge(Me)₃NEt₂, Ge(i-Bu)₃H, Ge(nBu)₄, Sb(GeEt₃)₃ and/or Ge(Cp)₂.

The antimony precursor may include Sb(iBu)₃, SbCl₃, SbCl₅, Sb(Me)₃, Sb(Et)₃, Sb(iPr)₃, Sb(tBu)₃, Sb[N(Me)₂]₃ and/or Sb(Cp)₃.

The tellurium precursor may include Te(iBu)₂, TeCl₄, Te(Me)₂, Te(Et)₂, Te(nPr)₂, Te(iPr)₂ and/or Te(tBu)₂.

The first process gas may be injected at least twice during the first process such that the first injection time of the first process gas occurs at least twice during the first process.

The fourth process gas may be injected at least twice during the third process such that the second injection time of the fourth process gas occurs at least twice during the third process.

The first and second injection times of the first and fourth process gases may be different from each other.

Each of the first and second pause times of the first and fourth process gases is equal to and/or about 0.05 seconds to about 0.1 seconds.

The second process gas may remove the first process gas from the process chamber in response to the first pause and elimination times, and may remove the fourth process gas from the process chamber in response to the second pause and elimination times.

The second process gas may include N₂ and/or Ar.

Each of the first and second elimination times may be equal to and/or about 0.5 seconds to about 1.0 seconds.

The third process gas may include H₂, NH₃, N₂H₄, SiH₄, B₂O₆, O₂, O₃ and/or H₂O.

The first, second, third, and fourth processes may be performed under an atmosphere including a pressure that is equal to and/or about 1.0 Torr to about 7.0 Torr, and a temperature that is equal to and/or about 220° C. to about 500° C. in the process chamber.

### BRIEF DESCRIPTION OF THE DRAWINGS

The above and other features and advantages will become more apparent to those of ordinary skill in the art by describing in detail exemplary embodiments with reference to the attached drawings, in which:

FIG. 1 illustrates a flowchart of an exemplary method of forming an information storage pattern according to exemplary embodiments;

FIG. 2 illustrates a timing diagram of exemplary injection times of process gases according to exemplary embodiments;

FIGS. 3, 4, 5 and 6 illustrate cross-sectional views of intermediate stages resulting during formation an information storage pattern according to the exemplary method of FIG. 1;

FIG. 7 illustrates a distribution chart of atoms resulting from an information storage pattern according to a conventional art; and

FIG. 8 illustrates a distribution chart of atoms resulting from an information storage pattern according to exemplary embodiments.

### DETAILED DESCRIPTION

Korean Patent Application No. 10-2009-0026420, filed on Mar. 27, 2009, in the Korean Intellectual Property Office, and entitled: “Method of Forming Information Storage Pattern,” is incorporated by reference herein in its entirety.

Exemplary embodiments will be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey the scope of the invention to those skilled in the art.

In the drawing figures, the dimensions of layers and regions may be exaggerated for clarity of illustration. It will also be understood that when an element, e.g., layer, film, is referred to as being “on” or “above” another element, it can be directly on or above the other element, or intervening elements may also be present. It will also be understood that when an element is referred to as being “below” or “under” another element, it can be directly below or under the other element, or intervening elements may also be present. In addition, it will also be understood that when an element is referred to as being “between” two elements, it can be the only element between the two elements, or one or more intervening elements may also be present. As used herein, the term “and/or” includes any and all combinations of one or more of the associated listed items. Further, as used herein, the singular forms “a,” “an” and “the” are intended to include the plural forms as well, unless the context clearly indicates otherwise.

Also, as used herein, terms such as “first,” “second,” and “third” are used to various regions, steps, and/or elements, the regions, processes, and/or the elements are not limited to these terms. These terms are used only to tell one region, step, or layer, etc. from another region, step, or layer, etc. Therefore, an element referred to as a first element in one embodiment may be referred to as a second element in another embodiment. Further, embodiments described and exemplified herein include complementary embodiments thereof. Like reference numerals refer to like elements throughout the specification.

As used herein, the term “analysis of an information storage pattern” has been well-known to one of ordinary skill in the field of a phase change memory device, and thus analysis equipment and an analysis method thereof will not be described in detail. The terminology used herein is for the purpose of describing particular embodiments only and is not intended to be limiting of the inventive concept.

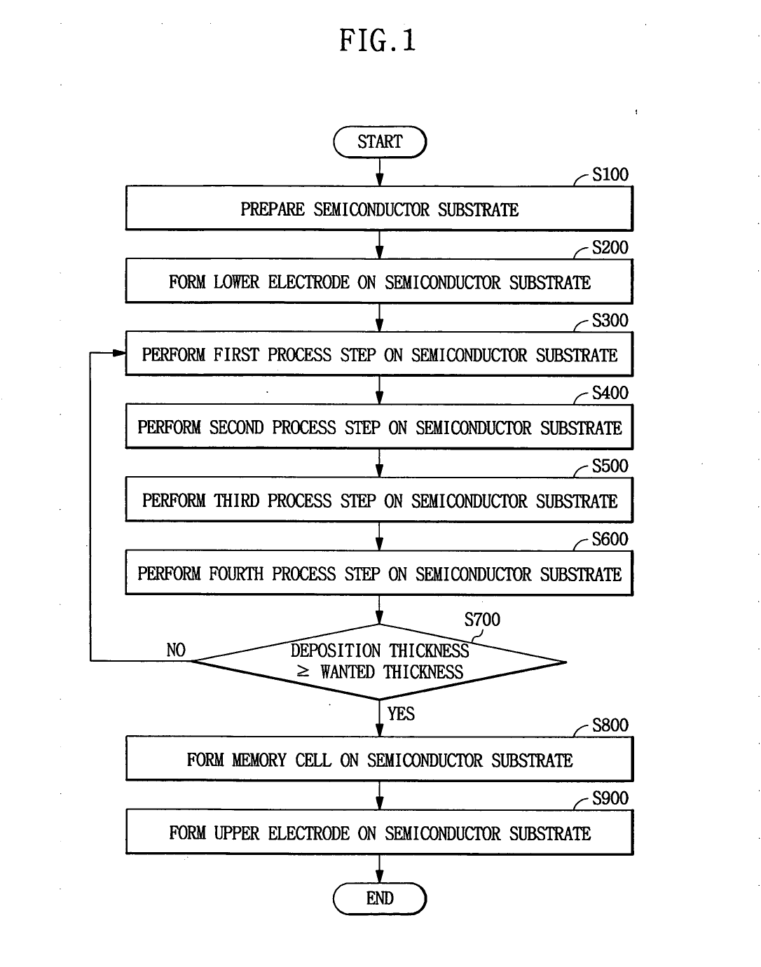

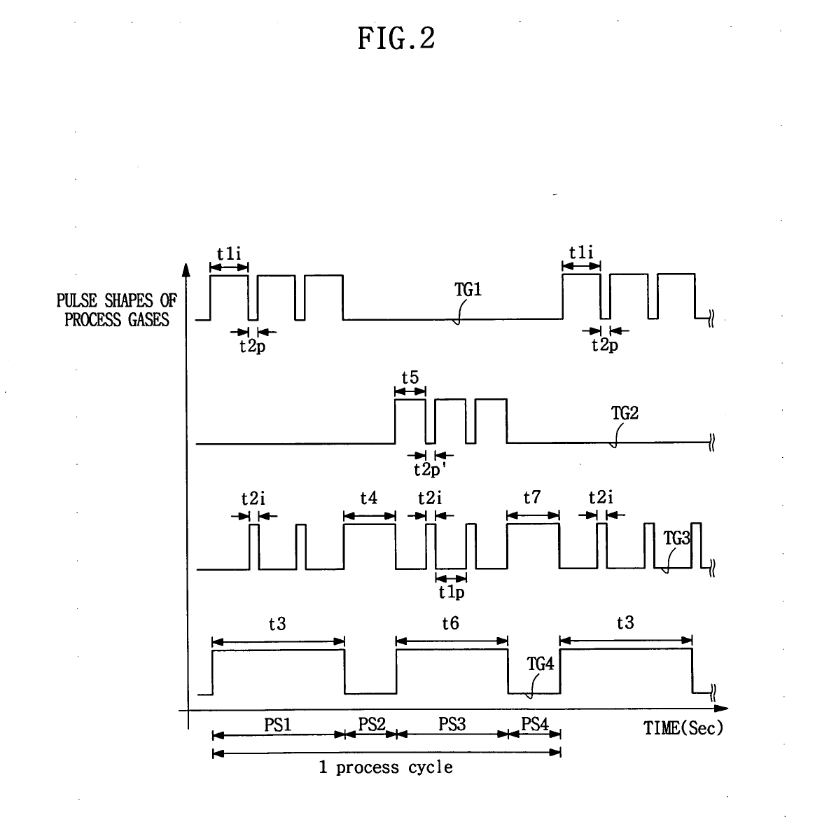

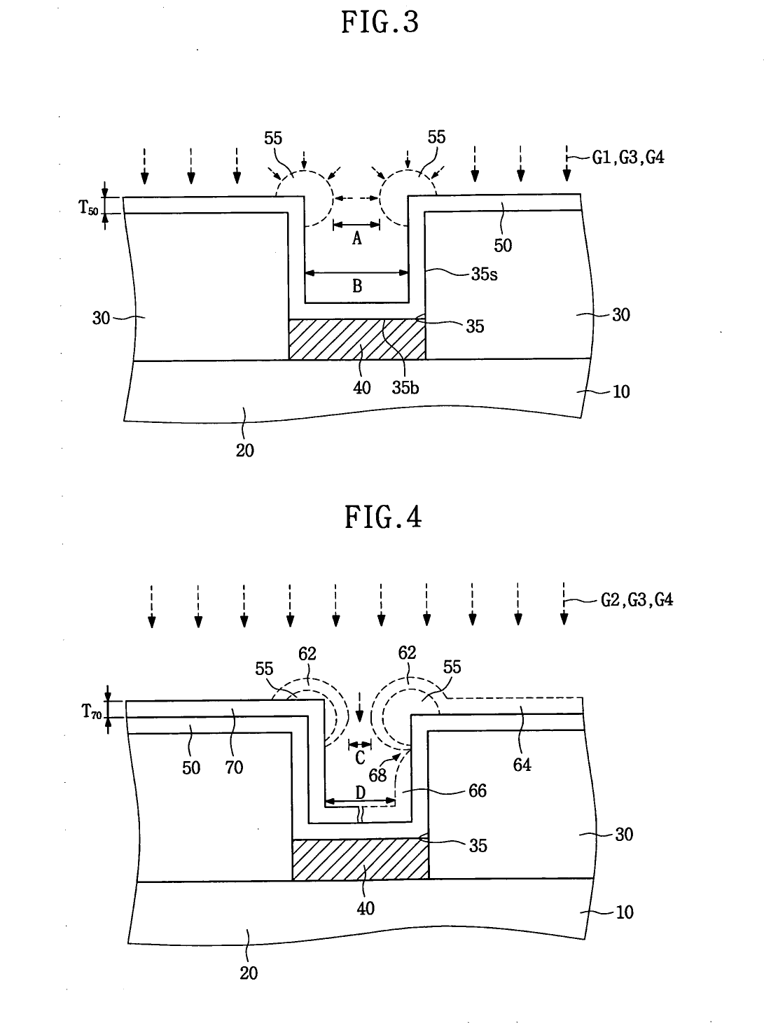

FIG. 1 illustrates a flowchart of an exemplary method of forming an information storage pattern according to exemplary embodiments. FIG. 2 illustrates a timing diagram of exemplary injection times of process gases according to exemplary embodiments. FIGS. 3, 4, 5 and 6 illustrate cross-sectional views of intermediate stages resulting during formation an information storage pattern according to the exemplary method of FIG. 1.

Referring to FIGS. 1, 2, and 3, a semiconductor substrate 10 may be prepared (S100) in accordance with the exemplary flowchart of FIG. 1. The semiconductor substrate 10 may include an active region 20. The semiconductor substrate 10 may include a transistor or a diode (not shown) on the active region 20. The diode may be formed to protrude from the semiconductor substrate 10. An interlayer insulating layer 30 may be formed in the semiconductor substrate 10 to surround the transistor or the diode. The interlayer insulating layer 30 may have an opening 35 exposing the transistor or the diode.

Referring to S200 in flowchart of FIG. 1, a lower electrode 40 may be formed in the opening 35 of the interlayer insulating layer 30, as illustrated in FIG. 3. The lower electrode 40 may be formed of a conductive material, e.g., a material containing titanium (Ti) atoms. The lower electrode 40 may be formed to partially fill the opening 35 of the interlayer insulating layer 30. In such a case, the lower electrode 40 may be in contact with a source region or a drain region of the transistor. Alternatively, e.g., the lower electrode 40 may be in contact with the diode.

Referring to S300 in flowchart of FIG. 1, the semiconductor substrate 10 may be loaded into a process chamber (not shown) of semiconductor deposition equipment. More particularly, referring to FIGS. 2 and 3, a first process (PS1) may be performed on the semiconductor substrate 10. In the semiconductor deposition equipment, a chemical vapor deposition technique may be employed. The first process (PS1) may be included in a selected process cycle of exemplary embodiments. The chemical vapor deposition technique may enable one or more gases, e.g., first, third and fourth process gases G1, G3 and G4, to be injected into the process chamber during the first process (PS1).

More particularly, e.g., the first process gas G1 may be injected into the process chamber according to a timing graph TG1 of FIG. 2. The timing graph TG1 may have pulse shape, in which a first injection time t1i and a first pause time t2p are periodically and repeatedly used. The first injection time t1i may be exhibited at least twice during the first process (PS1). For example, the first injection time t1i may be 0.54 second, and the first pause time t2p may be equal to and/or about 0.05 seconds to about 0.1 seconds.

The third process gas G3 may be injected into the process chamber during a time period corresponding to the first pause time t2p of the first process gas G1. Referring to FIG. 2, the third process gas G3 may be injected into the process chamber according to a timing graph (TG3), such that a pause time t1p of the third process gas G3 may correspond to the first injection time t1i and an injection time t2i of the third process gas G3 may correspond to the first pause time t2p. The timing graph (TG3) may have a pulse shape, in which the pause time t1p and the injection time t2i of the third process gas G3 may correspond to the first injection time t1i and the first pause time t2p, respectively, of the first process gas G1.

During the first process PS1, the fourth process gas G4 may be injected into the process chamber during a time period corresponding to the first injection and pause times t1i and t2p of the first process gas G1. More particularly, the fourth process gas G4 may be injected into the process chamber according to a timing graph TG4 of FIG. 2, in which an injection time t3 of the fourth process gas G4 may correspond to the injection times t1i and t2i of the first and third process gases G1 and G3, respectively, such that, e.g., the fourth process gas G4 may correspond to x (t1i)+y(t2i), where x, y are integers. The timing graph TG4 may have a pulse shape corresponding to an injection time t3 of the fourth process gas G4.

The first process gas G1 may be a first source gas including, e.g., a mixture of a germanium precursor and a tellurium precursor. The germanium precursor may include, e.g., Ge(i-Pr)₃H, GeCl₄, Ge(Me)₄, Ge(Me)₄N₃, Ge(Et)₄, Ge(Me)₃NEt₂, Ge(i-Bu)₃H, Ge(nBu)₄, Sb(GeEt₃)₃ and/or Ge(Cp)₂. The tellurium precursor may include, e.g., Te(iBu)₂, TeCl₄, Te(Me)₂, Te(Et)₂, Te(nPr)₂, Te(iPr)₂ and/or Te(tBu)₂.

The third process gas G3 may be a purge gas including, e.g., N2 and/or Ar. The third process gas G3 may enable the first process gas G1 to be removed from the process chamber. The fourth process gas G4 may be a reaction gas including, e.g., H₂, NH₃, N₂H₄, SiH₄, B₂O₆, O₂, O₃ and/or H₂O. The fourth process gas G4 may chemically react with the first process gas G1 to generate reactive materials. The first, third and fourth process gases G1, G3 and G4 may form a lower layer 50 on the semiconductor substrate 10 during the first process (PS1), as illustrated in FIG. 3.

During the first process PS1, the lower layer 50 may be conformally formed on the interlayer insulating layer 30 to cover the lower electrode 40. That is, e.g., the lower layer 50 may be formed by adjusting the chemical reaction of the first and fourth process gases G1 and G4 through the third process gas G3. More particularly, e.g., since the third process gas G3 may be injected during the first pause time t2p of the first process gas G1, a vapor reaction of the first and fourth process gases G1 and G4 may be adequately adjusted.

As a result of adjusting the vapor reaction, the third process gas G3 may prevent reactive materials of the first and fourth process gases G1 and G4 from being excessively deposited at an entrance of the opening 35 of the interlayer insulating layer 30. Accordingly, the reactive materials of the first and fourth process materials G1 and G4 may be uniformly deposited on a bottom surface 35b and a sidewall 35s of the opening 35. The lower layer 50 may be formed to a uniform thickness on the bottom surface 35b and the sidewalls 35s of the opening 35. Therefore, a width of the entrance of the opening 35 may be reduced corresponding to a thickness T₅₀ of the lower layer 50, e.g., reduced by twice the thickness T₅₀ of the lower layer 50, so that it may be changed to a predetermined width B.

Embodiments may have good profile over comparable conventional devices by providing a conformally formed lower layer, e.g., 50, having a substantially and/or completely uniform thickness, e.g., T₅₀ throughout, including portions thereof formed along corner/entrance portions, sidewalls and/or bottom surfaces of an opening, e.g., 35. More particularly, e.g., embodiments may have good profile over comparable conventional devices by conformally forming a lower layer on an opening while establishing a substantially and/or completely constant width, e.g., B, from an upper portion to a lower portion of the opening. More specifically, embodiments employing the above described herein may prevent and/or suppress more of reactive materials, e.g., the first and fourth process gases G1 and G4, from being three-dimensionally deposited along a circumference of an entrance of an opening, e.g., 35, than other portions of the opening.

Referring to FIG. 3, in comparable conventional cases in which a lower layer is not formed so as to have a substantially and/or completely uniform thickness at, e.g., an entrance of an opening in an interlayer insulating layer, a width, e.g., A, at the opening entrance may be smaller than a width, e.g., B, at, e.g., lower portions of the opening. More particularly, in such conventional cases in which a protrusion portion 55 is formed at the entrance of the opening, the width A at the opening entrance may be smaller than the width B at lower portions of the opening. That is, in such conventional cases, such thickness and/or width variations may occur when, e.g., reactive materials of process gases employed for forming a lower layer are deposited on a semiconductor substrate without adjusting a deposition rate thereof.

Referring to FIGS. 1, 2 and 4, referring to S400 in flowchart of FIG. 1, a second process (PS2) of FIG. 2 may be performed on the semiconductor substrate 10, as illustrated in FIG. 4. The second process (PS2) may be included in the selected process cycle of the exemplary embodiments. The second process (PS2) may be performed during a predetermined time period beginning from a time when the injection of the first and fourth process gases G1 and G4 of the first process (PS1) into the process chamber is completed. During the second process (PS2), a third process gas G3 may be injected into a process chamber using a chemical vapor deposition process.

During the second process PS2, the third process gas G3 may be injected into the process chamber during the second process (PS2) according to the timing graph TG3 of FIG. 2. The timing graph TG3 may have a pulse shape corresponding to a first elimination time t4 of the third process gas G3. The first elimination time t4 may be equal to and/or about 0.5 seconds to about 1.0 second. In such a case, the third process gas G3 may enable substantially and/or completely all of the first and fourth process gases G1 and G4 of the first process (PS1) existing in the process chamber to be removed from the process chamber.

As a result, during the second process PS2, the third process gas G3 may enable the thickness T₅₀ of the lower layer of FIG. 4 to be constantly maintained on a surface of the interlayer insulating layer 30 and the bottom surface 35b and the sidewall 35s of the opening 35. Referring to S500 in flowchart of FIG. 1, the third process (PS3) of FIG. 2 may be performed on a semiconductor substrate, as illustrated in FIG. 4. The third process (PS3) may be included in the selected process cycle of the exemplary embodiments. In the third process (PS3), the second, third and fourth process gases G2, G3 and G4 may be injected into the process chamber using a chemical vapor deposition technique.

In such embodiments, during the third process PS3, the second process gas G2 may be injected into the process chamber according to the timing graph TG2 of FIG. 2. The timing graph TG2 may have the shape of a pulse periodically and repeatedly using a second injection time t5 and a second pause time t2p′. The second injection time t5 may be exhibited at least twice during the third process (PS3). More particularly, e.g., the second injection time t5 may be equal to and/or about 0.33 second. The second injection time t5 may be equivalent to the first injection time t1i of FIG. 3. The second pause time t2p′ may be equal to and/or about 0.05 seconds to about 0.1 seconds.

During the third process PS3, the third process gas G3 may be injected into the process chamber during a time period corresponding to the second pause time t2p′ of the second process gas G2. The third process gas G3 may be injected into the process chamber according to the timing graph TG3 of FIG. 2, in which the pause time t1p of the third process gas G3 may correspond to the second injection time t5, and an injection time t2i of the third process gas G3 may correspond to the second pause time t2p′. The timing graph TG3 may have a pulse shape, in which the injection time t2i and the pause time t1p of the third process gas G3 may correspond to the second pause time t2p′ and the second injection time t5 of the second process gas G2, respectively.

During the third process PS3, the fourth process gas G4 may be injected into the process chamber during a time period corresponding to the second injection and pause times t5 and t2p′ of the second process gas G2. The fourth process gas G4 may be injected into the process chamber according to the timing graph TG4 of FIG. 2, in which an injection time corresponds to the injection times t5 and t2i of the second and third process gases G2 and G3. The timing graph TG4 may have a shape of a pulse corresponding to an injection time t6 of the fourth process gas G4, such that, e.g., the fourth process gas G4 may correspond to x(t5)+y(t2i), where x and y are integers.

The second process gas G2 may be a second source gas including, e.g., a mixture of an antimony precursor and a tellurium precursor. The antimony precursor may include Sb(iBu)₃, SbCl₃, SbCl₅, Sb(Me)₃, Sb(Et)₃, Sb(iPr)₃, Sb(tBu)₃, Sb[N(Me)₂]₃ and/or Sb(Cp)₃. The third process gas G3 may enable the second process gas G2 to be removed from the process chamber. The fourth process gas G4 may generate reactive materials by chemically reacting with the second process gas G2.

Referring to FIG. 4, the second, third and fourth process gases G2, G3, and G4 may form an upper layer 70 on the semiconductor substrate 10 during the third process (PS3). The tellurium precursor may include, e.g., Te(iBu)₂, TeCl₄, Te(Me)₂, Te(Et)₂, Te(nPr)₂, Te(iPr)₂ and/or Te(tBu)₂. In some embodiments, the upper layer 70 may be formed on only a selected region within the opening 35 and the interlayer insulating layer 30 defining the selected region with respect to a central region of the opening 35 of the interlayer insulating layer 30. The upper layer 70 may be disposed on the lower layer 50 to be conformally formed along the opening 35.

This is because the upper layer 70 may be formed by adequately adjusting a chemical reaction of the second and fourth process gases G2 and G4 through the third process gas G3. That is, the third process gas G3 may be injected during the first pause time t2p′ of the second process gas G2, and thus the vapor reaction of the second and fourth process gases G2 and G4 may be adjusted on the semiconductor substrate 10. As a result of adjusting the vapor reaction, the third process gas G3 may prevent the reactive materials of the second and fourth process gases G2 and G4 from being excessively deposited at the entrance of the opening 35 of the interlayer insulating layer 30.

Accordingly, embodiments may enable the reactive materials of the second and fourth process gases G2 and G4 to be uniformly formed on the bottom surface 35b and the sidewall 35s of the opening 35. The upper layer 70 may be formed to have a uniform thickness T₇₀ on the bottom surface 35b and the sidewall 35s of the opening 35. Therefore, the width of the entrance of the opening 35 may be narrowed as much as the thickness of the upper layer 70. In contrast, upper layers 62, 64 and 66 according to the conventional art may be formed on the remaining region in the opening 35 and on the interlayer insulating layer 30 defining the remaining region. More specifically, embodiments employing the above described herein may prevent and/or suppress more or less of reactive materials, e.g., the second and fourth process gases G2 and G4, from being un-uniformly and/or three-dimensionally deposited along a circumstance of an entrance of an opening, e.g., 35, than other portions of the opening.

Referring to FIG. 4, in comparable conventional cases in which an upper layer is not formed so as to have a substantially and/or completely uniform thickness at, e.g., an entrance of an opening in an interlayer insulating layer, a width, e.g., C, at the opening entrance may be smaller than a width, e.g., D, at lower portions of the opening. More particularly, in such conventional cases in which a protrusion 62 may be formed while forming the upper layer, the width C at the opening entrance may be smaller than the width D at lower portions of the opening. Further, in conventional cases in which the protrusion 55 resulted during formation of the lower layer, a separation portion 66 of the upper layer within the opening may have a reducing thickness and/or a portion of the opening to be narrowed. In such cases, protrusion portion 62 and the separation portion 66 may form a void-forming region 68 in the opening 35. That is, in such conventional cases, such thickness and/or width variations may occur when, e.g., reactive materials of process gases employed for forming an upper layer are deposited on a semiconductor substrate without adjusting a deposition rate thereof.

Referring to FIGS. 1, 2, and 5, and referring to S600 of FIG. 1, the fourth process (PS4) of FIG. 2 may be performed on the semiconductor substrate 10, as illustrated in FIG. 5. The fourth process (PS4) may be included in the selected process cycle of the exemplary embodiments. The fourth process (PS4) may be performed during a predetermined time period beginning from a time when the injection of the second and fourth process gases G2 and G4 of the third process (PS3) into the process chamber is completed. In the fourth process (PS4), the third process gas G3 may be injected into the process chamber using a chemical vapor deposition technique.

The third process gas G3 may be injected into the process chamber during the fourth process (PS4) according to the timing graph TG3 of FIG. 2. The timing graph TG3 may have a shape of a pulse corresponding to a second elimination time t7 of the third process gas G3. The second elimination time t7 may be equal to and/or about 0.5 seconds to about 1.0 second. The second elimination time t7 may be equivalent to or different from the first elimination time t4 of the second process (PS2). In such a case, the third process gas G3 may enable all of the second and fourth process gases G2 and G4 of the third process (PS3) existing in the process chamber to be removed from the process chamber.

As a result, the third process gas G3 may enable the thickness of the upper layer 70 of FIG. 5 to be uniformly maintained on the surface of the interlayer insulating layer 30 and the bottom surface 35b and the sidewall 35s of the opening 35. After the completion of the first, second, third and fourth processes (PS1, PS2, PS3, PS4) of FIGS. 3, 4 and 5, processing may be completed. The selected process cycle may be performed under an atmosphere including a numerical value selected from a pressure equal to and/or about 1.0 Torr to about 7.0 Torr, and a numerical value selected from a temperature equal to and/or about 220° C. to about 500° C. in the process chamber.

Referring to S700 of FIG. 1, the thickness T₅₀ of the lower layer 50 and the thickness T₇₀ of the upper layer 70 may be compared with a wanted thickness T using an electronic measurement apparatus, as illustrated in FIG. 5. When the thickness T₅₀, T₇₀ of the lower layer 50 and the upper layer 70 is smaller than the desired thickness T, the selected process cycle may be repeatedly performed at least once until the targeted thickness T is accomplished, so that a buried layer 80 may be formed, as illustrated in FIG. 5.

The buried layer 80 may be formed using the first, second, third and fourth process gases G1, G2, G3 and G4. The buried layer 80 may be formed on the upper layer 70 along a growth line GL. The buried layer 80 may be formed on the upper layer 70 to fill the opening 35 of the interlayer insulating layer 30. A thickness of the buried layer 80 may reach the wanted thickness T. The buried layer 80 may be in a stacked structure having the lower layer 50 and the upper layer 70 in a periodic and repeated manner. The lower layer 50, the upper layer 70 and the buried layer 80 may constitute a stacked layer 100. Afterwards, processing may depend on whether the thickness T₅₀, T₇₀ of the lower layer 50 and the upper layer 70 and the thickness of the buried layer 80 equals to or is greater than the desired thickness T. If the thickness T₅₀, T₇₀ of the lower layer 50 and the upper layer 70 and the thickness of the buried layer 80 is equal to and/or greater than the desired thickness T, process S800 of FIG. 1 may be performed. If the thickness T₅₀, T₇₀ of the lower layer 50 and the upper layer 70 and/or the thickness of the buried layer 80 is not equal to and/or greater than the desired thickness T, processes S300-S700 may be repeated. In such a case, the lower layer 50 and the upper layer 70 may be formed of the stacked layer 100.

Referring to FIGS. 1 and 6, a memory cell 110 may be formed on a semiconductor substrate 10 based on the process flowchart (S800) of FIG. 1. For this purpose, the stacked layer 100 of FIG. 5 may be etched to expose the interlayer insulating layer 30, so that the memory cell 110 may be formed, as illustrated in FIG. 6. The memory cell 110 may be disposed on the lower electrode 40 and may fill the opening 35 of the interlayer insulating layer 30. After the memory cell 110 is formed, an upper electrode 120 may be formed on the semiconductor substrate 10 based on the flowchart (S900) of FIG. 1, as illustrated in FIG. 6.

For this purpose, a conductive layer may be formed on the interlayer insulating layer 30 to cover the memory cell 110. The conductive layer may have a material containing a conductive material, e.g., titanium atoms. The conductive layer may be etched to expose the interlayer insulating layer 30, so that the upper electrode 120 may be formed. The upper electrode 120 together with the lower electrode 40 and the memory cell 110 may constitute an information storage pattern 130 according to exemplary embodiments as illustrated in FIG. 6.

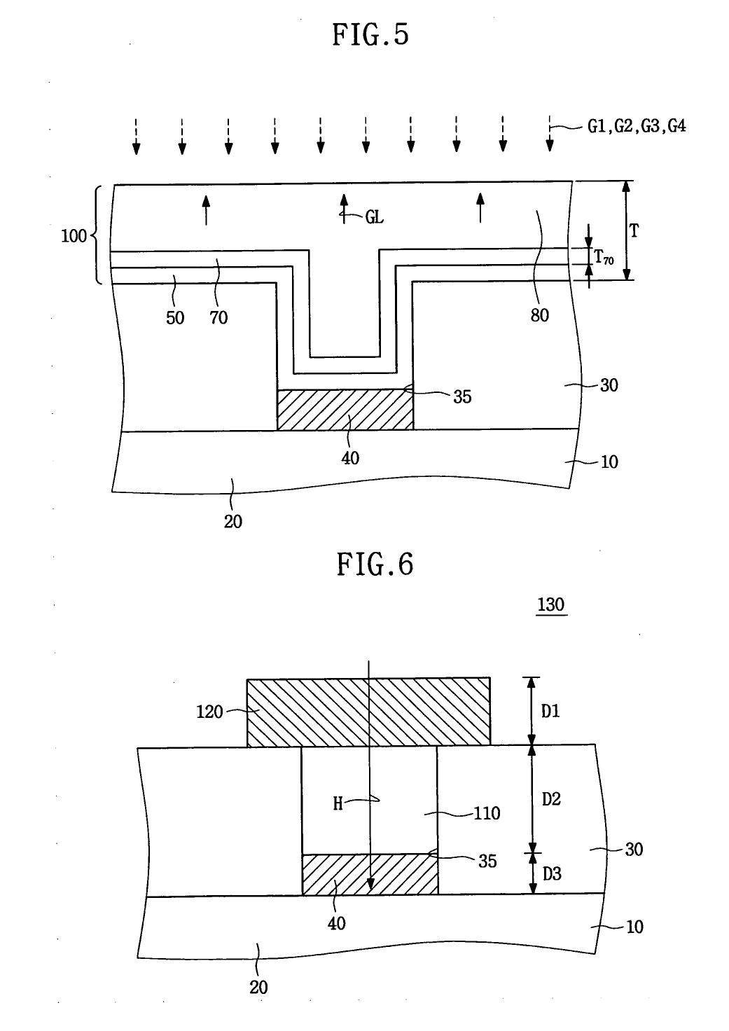

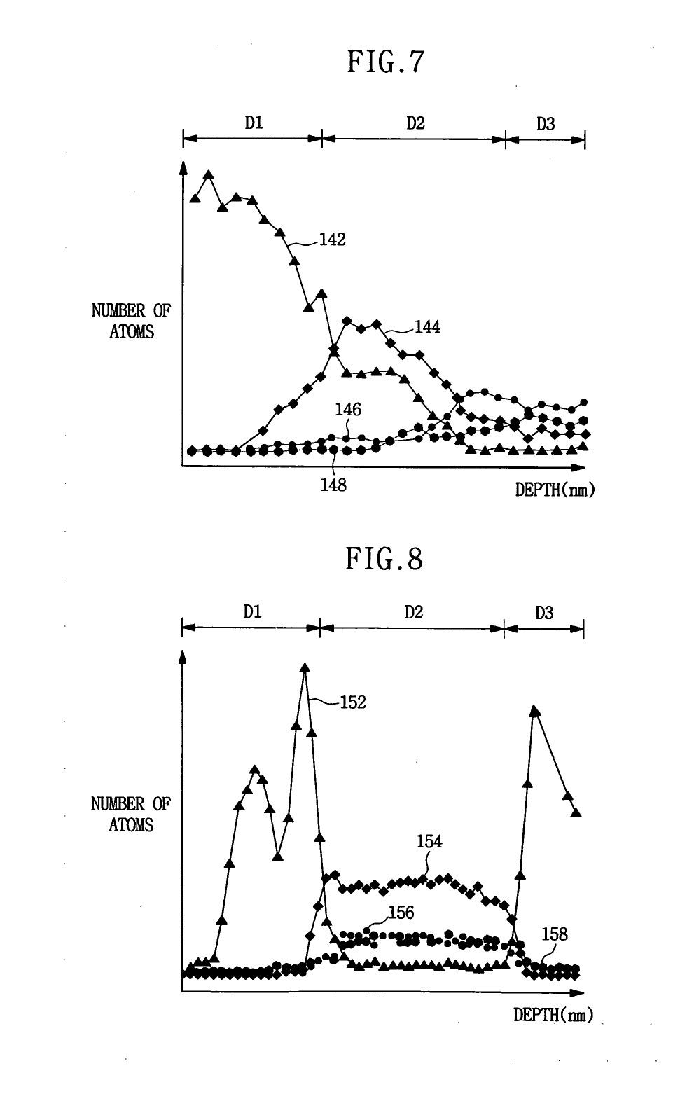

FIG. 7 illustrates a distribution chart of atoms resulting from an information storage pattern according to a conventional art. FIG. 8 illustrates a distribution chart of atoms resulting from an information storage pattern according to exemplary embodiments.

Referring to FIG. 7, and as discussed above with regard to, e.g., protrusions 55, 62 and/or void 68 (FIGS. 3 and 4) in conventional cases, a seam and/or a void may result in the memory cell. More particularly, in conventional cases, the seam may be formed in the central region of the opening of the interlayer insulating layer through, e.g., the protrusion 55 of FIG. 3 and the protrusion 62 of FIG. 4. That is, in such conventional cases the void may be formed since a part beneath the void-forming region 68 may not be filled with a buried layer. Furthermore, in such conventional cases, the memory cell according to the conventional art may not have uniform distribution of atoms due to the protrusions 55 and 62 of FIGS. 3 and 4. In order to confirm the distribution of the atoms, the information storage pattern according to such conventional cases were analyzed along an arrow H of FIG. 6. The distribution of the atoms is illustrated in a graph by specifying the information storage pattern into an upper electrode region D1, a memory cell region D2 and a lower electrode region D3.

In the graph, analysis depth according to a direction of the arrow H of FIG. 6 may be plotted on the X axis, and the number of atoms according to the analysis depth may be plotted on the Y axis. The number of atoms may be proportional to an occupancy rate of the atoms in the upper electrode region D1, the memory cell region D2 and the lower electrode region D3. In such a case, the upper electrode region D1 has more titanium atoms 142 than the memory cell region D2 and the lower electrode region D3. The memory cell region D2 has more germanium (Ge), antimony (Sb) and tellurium (Te) atoms 144, 146 and 148 than the upper electrode region D1 and the lower electrode region D3.

However, the memory cell region D2 does not have uniform distribution of germanium (Ge), antimony (Sb) and tellurium atoms 144, 146 and 148 therein. Moreover, the memory cell region D2 has more titanium atoms 142 therein than the lower electrode region D3. The lower electrode region D3 has less titanium atoms 142 than the upper electrode region D1 and the memory cell region D2. This is because a lower electrode and/or an upper electrode according to the conventional art fill a void or a seam.

Referring to FIG. 8, an information storage pattern 130 according to exemplary embodiments does not have a seam and/or a void in a memory cell 110. For example, embodiments may provide the memory cell 110, which may be free of, e.g., protrusions 55 and 62, and thus, uniform distribution of atoms may be exhibited. In order to confirm the distribution of the atoms, the information storage pattern 130 according to the exemplary embodiments was analyzed along the arrow H of FIG. 6. The distribution of the atoms was illustrated in the graph by specifying the information storage pattern into an upper electrode region D1, a memory cell region D2 and a lower electrode region D3.

The X and Y axes may be the same as those of the graph of FIG. 7. In such a case, the upper electrode region D1 may have more titanium atoms 152 than the memory cell region D2 and the lower electrode region D3. The memory cell region D2 has more Ge, Sb and Te atoms 154, 156, and 158 than the upper electrode region D1 and the lower electrode region D3. The memory cell region D2 may have uniform distribution of the Ge, Sb and tellurium atoms 154, 156, and 158 therein.

In comparison to the conventional case of FIG. 7, in exemplary embodiment of FIG. 8, the lower electrode region D3 has more titanium atoms 152 than the memory cell region D2. More particularly, in embodiments, the lower electrode 40 and the upper electrode 120 may be completely separated from each other by the memory cell 110.

As described above, a method of forming an information storage pattern capable of uniformly maintaining a ratio of atoms in a memory cell in contact with a lower electrode on a semiconductor substrate may be provided. Furthermore, in the exemplary embodiments, a vapor reaction of source gases and a reaction gas may be adequately adjusted while a chemical vapor deposition technique is applied on a semiconductor substrate, so that generation of a void and/or a seam in the memory cell may be prevented. As a result, a resistance of the memory cell according to the exemplary embodiments may be uniformly maintained, so that electrical characteristics of a phase change memory device may be enhanced.

The foregoing is illustrative of exemplary embodiments and is not to be construed as limiting thereof. Although a few exemplary embodiments have been described, those skilled in the art will readily appreciate that many modifications are possible in exemplary embodiments without materially departing from the novel teachings and advantages. Accordingly, all such modifications are intended to be included within the scope of this inventive concept as defined in the claims. Therefore, it is to be understood that the foregoing is illustrative of various exemplary embodiments and is not to be construed as limited to the specific embodiments disclosed, and that modifications to the disclosed embodiments, as well as other embodiments, are intended to be included within the scope of the appended claims.

What is claimed is:

1. A method of forming an information storage pattern, comprising:
placing a semiconductor substrate in a process chamber of semiconductor deposition equipment;
injecting first, second and third process gases into the process chamber during a first process to form a lower layer on the semiconductor substrate in accordance with a first injection time and/or a first pause time;
injecting the second process gas into the process chamber during a second process, wherein the second process gas is injected into the process chamber during a first elimination time after completing the first process;
injecting a fourth process gas together with the second and third process gases into the process chamber during a third process in accordance with a second injection time and/or a second pause time to form an upper layer on the lower layer; and
injecting the second process gas into the process chamber during a fourth process, wherein the second process gas is injected into the process chamber during a second elimination time after completing the third process.

2. The method as claimed in claim 1, wherein:
the first process gas is periodically and repeatedly injected in accordance with the first injection time and the first pause time, and
the second process gas is injected into the process chamber during periods corresponding to the first pause time, and
the third process gas is injected into the process chamber during periods corresponding to the first injection time and the first pause time.

3. The method as claimed in claim 1, wherein the semiconductor substrate includes an interlayer insulating layer and a lower electrode, the interlayer insulating layer includes an opening.

4. The method as claimed in claim 3, further comprising:
periodically and repeatedly performing the first, second, third, and fourth processes at least once, and to form a stacked layer on the semiconductor substrate, wherein the stacked layer includes a stacked structure having the lower layer and the upper layer in a periodic and repeated manner, and the stacked layer is formed to fill the opening and cover the interlayer insulating layer;
etching the stacked layer to expose the interlayer insulating layer, and to form a memory cell in the opening; and
forming an upper electrode on the interlayer insulating layer to cover the memory cell.

5. The method as claimed in claim 3, wherein the lower electrode at least partially fills the opening, and injecting the first, second and third process gases includes forming the lower layer on the interlayer insulating layer to cover the lower electrode, and the lower layer includes a phase change material conformally covering the opening.

6. The method as claimed in claim 3, wherein the upper layer includes a phase change material conformally covering the opening.

7. The method as claimed in claim 1, wherein:
the fourth process gas is periodically and repeatedly injected in accordance with the second injection time and the second pause time,
the second process gas is injected into the process chamber in accordance with the second pause time, and
the third process gas is injected into the process chamber during time periods corresponding to the second injection and pause times.

8. The method as claimed in claim 1, wherein the first process gas and the fourth process gas include a mixture of a germanium precursor and a tellurium precursor, and a mixture of an antimony precursor and a tellurium precursor, respectively.

9. The method as claimed in claim 8, wherein the germanium precursor includes Ge(i-Pr)₃H, GeCl₄, Ge(Me)₄, Ge(Me)₄N₃, Ge(Et)₄, Ge(Me)₃NEt₂, Ge(i-Bu)₃H, Ge(nBu)₄, Sb(GeEt₃)₃ and/or Ge(Cp)₂.

10. The method as claimed in claim 8, wherein the antimony precursor includes Sb(iBu)₃, SbCl₃, SbCl₅, Sb(Me)₃, Sb(Et)₃, Sb(iPr)₃, Sb(tBu)₃, Sb[N(Me)₂]₃ and/or Sb(Cp)₃.

11. The method as claimed in claim 8, wherein the tellurium precursor includes Te(iBu)₂, TeCl₄, Te(Me)₂, Te(Et)₂, Te(nPr)₂, Te(iPr)₂ and/or Te(tBu)₂.

12. The method as claimed in claim 1, wherein the first process gas is injected at least twice during the first process such that the first injection time of the first process gas occurs at least twice during the first process.

13. The method as claimed in claim 1, wherein the fourth process gas is injected at least twice during the third process such that the second injection time of the fourth process gas occurs at least twice during the third process.

14. The method as claimed in claim 1, wherein the first and second injection times of the first and fourth process gases are different from each other.

15. The method as claimed in claim 1, wherein each of the first and second pause times of the first and fourth process gases is equal to and/or about 0.05 seconds to about 0.1 seconds.

16. The method as claimed in claim 1, wherein the second process gas removes the first process gas from the process chamber in response to the first pause and elimination times, and removes the fourth process gas from the process chamber in response to the second pause and elimination times.

17. The method as claimed in claim 1, wherein the second process gas includes N₂ and/or Ar.

18. The method as claimed in claim 1, wherein each of the first and second elimination times is equal to and/or about 0.5 seconds to about 1.0 seconds.

19. The method as claimed in claim 1, wherein the third process gas includes H₂, NH₃, N₂H₄, SiH₄, B₂O₆, O₂, O₃ and/or H₂O.

20. The method as claimed in claim 1, wherein the first, second, third, and fourth processes are performed under an atmosphere including a pressure that is equal to and/or about 1.0 Torr to about 7.0 Torr, and a temperature that is equal to and/or about 220° C. to about 500° C. in the process chamber.
